(19) United States
(12) Patent Application Publication
(10) Pub. No.: US 2012/0186628 A1
(43) Pub. Date: Jul. 26, 2012

(54) Rapid deployable and reusable solar energy generation

(76) Inventor: Cameron McLear Paine, Madison, CT (US)

(21) Appl. No.: 12/930,909

(22) Filed: Jan. 20, 2011

(51) Int. Cl. H01L 31/048

(52) U.S. Cl. 136/251

(57) ABSTRACT

A method for the generation of electric power by deploying structurally protected and supported solar cell panels, such system including a substantial number of electrically and mechanically linked solar cell modules positioned upon surfaces of horizontal areas.

Solar cell modules are easily transportable, easily deployed, reusable, and designed specifically for dual use as both structural components allowing pedestrian and vehicular traffic and as electrical generators.

### BACKGROUND OF THE INVENTION

Immediately following disasters or emergency situations, electric power is a critical necessity for emergency responders. Currently, without connection to an electric grid, power can only be generated in significant amounts by generators, which require fuel, numerous and reliable transportation assets, and undamaged and/or secure road infrastructure. In situations where fuel cannot be transported reliably, safely, or economically, electricity generation via solar energy can be quickly deployed with a minimum of transportation assets.

### BRIEF SUMMARY OF PREFERRED EMBODIMENTS OF THE INVENTION

A system is provided for the rapid deployment, and re-deployment, of emergency generation of electric power by employing structurally supported solar cell panels, such system including a substantial number of electrically and mechanically linked solar cell modules positioned upon surfaces of horizontal areas. The structurally supported solar cells enable dual use for both electric generation and large horizontal area capable of supporting the weight of vehicles or pedestrians. This dual use enables protection of otherwise fragile solar generation modules while permitting rapid construction of an emergency base camp with electric power on any substantially flat area.

The solar cell modules are configured to support the weight of pedestrians or vehicles without damaging the modules, and wherein the solar cells of each module are positioned within associated support frame members that have sufficient strength for absorbing compressive forces of the vehicles or pedestrians without buckling. In addition, they are mechanically linked in such a way that can accommodate terrain features consistent with an emergency or non-prepared site by conforming.

### BRIEF DESCRIPTION OF THE DRAWINGS

Other features of the invention may become more apparent upon study of the following detailed description taken in conjunction with the drawings in which:

FIG. 1 illustrates and individual solar cell module showing mechanical and electrical linkages;

FIG. 2 illustrates an individual solar cell module cutaway with support structure enveloping multiple small ganged solar cells; and

FIG. 3 illustrates mechanical linking of solar cell modules together;

FIG. 4 illustrates various miscellaneous applications of the invention.

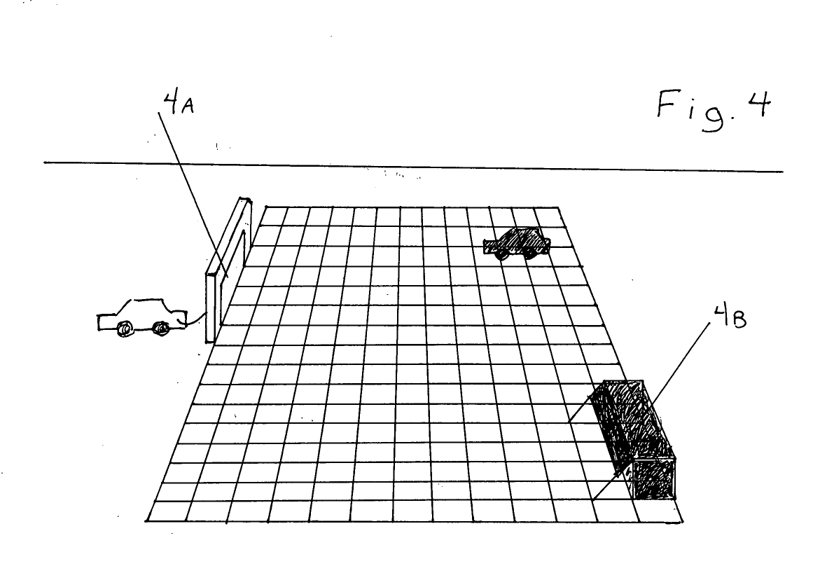

### DETAILED DESCRIPTION OF PREFERRED EMBODIMENTS OF THE INVENTION

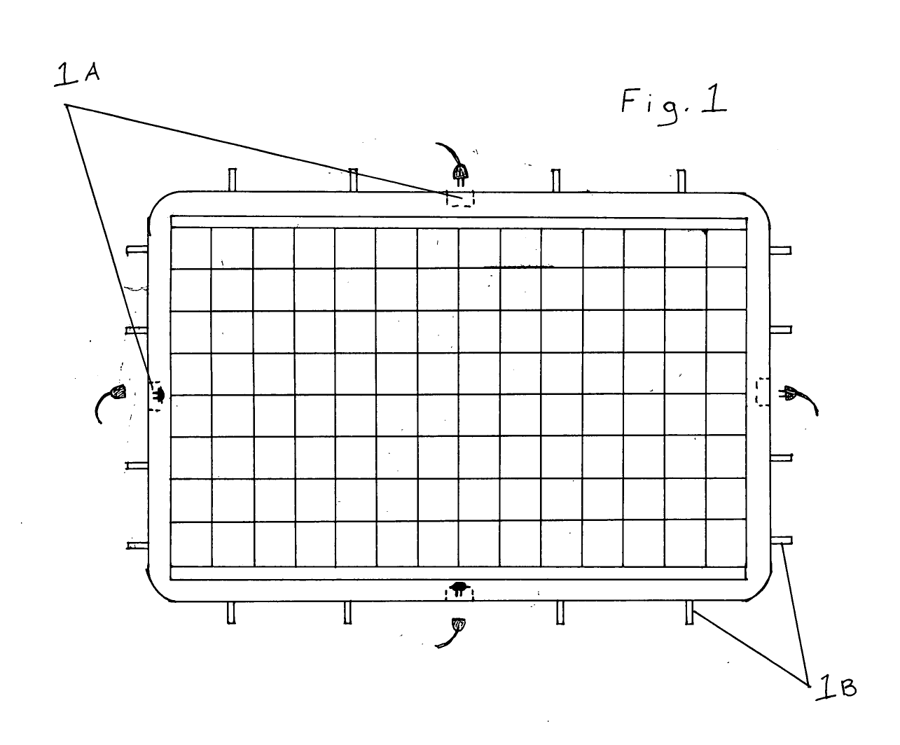

Solar cell modules may be deployed already ganged in a row or individually. If deployed individually, solar cell modules may be connected mechanically and electrically to the number of modules, shape, and/or size desired. An individual module is illustrated in FIG. 1. Rows may be ganged together both electrically 1A and mechanically 1B. When the emergency electrical supply is no longer needed, the solar modules may be re-deployed onto a truck or other mode transport for reuse elsewhere.

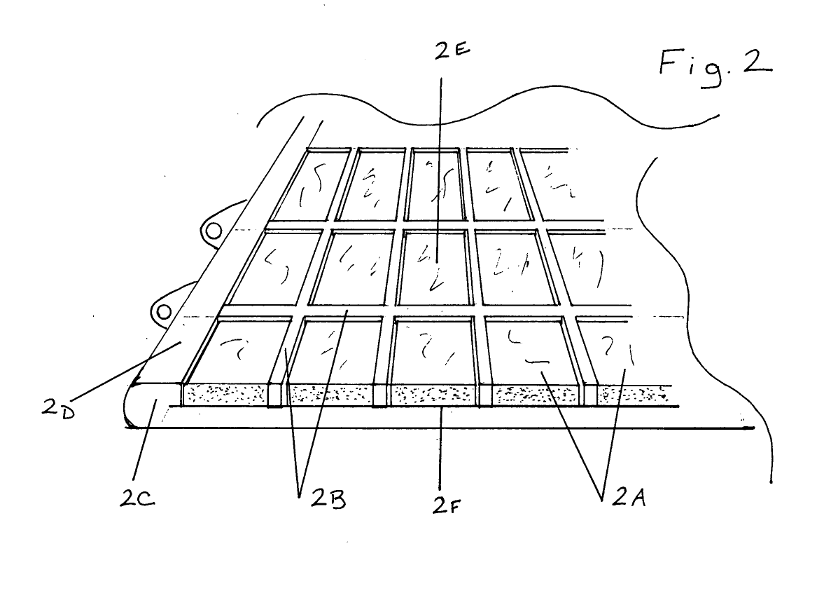

An individual module cut-away view is illustrated in FIG. 2 wherein the solar cells or tiles 2A, that may be rectangular, are positioned within a protective honeycomb structure 2B, in turn contained within a frame member 2C that has four wall portions 2D having sufficient strength for absorbing the weights of vehicles or pedestrians over the modules without buckling and possibly injuring the solar cells. The wall portions of the rectangular honeycomb 2B may also be employed to help absorb such compressive stresses.

Light transmissive protective layer 2E is positioned over the top of module 2. The protective shell bottom 2F supports a conventional circuit blanket for interconnecting the cells together in conventional serial/parallel fashion. The details of the interconnection of the cells and the interconnection between modules are omitted in the interest of clarity, brevity and economy as they are well known to workers in the art.

As stated in U.S. Pat. No. 6,350,944 issued to Sherif et al. Feb. 26, 2002: “Typically, a plurality of cells are supported on a substrate and electrically interconnected in a fixed pattern. The substrate may be rigid or flexible. The fixed pattern typically requires hard wired interconnects between solar cells on a solar cell assembly. Generally, a solar cell array will be mounted to a printed circuit board, and the individual solar cells will be wired together in a fixed pattern on the printed circuit board that is pre-defined before the solar panel assembly, by the specific application the solar cell array is designed for. There are many known methods of packaging and mounting solar cells to a printed circuit board.”

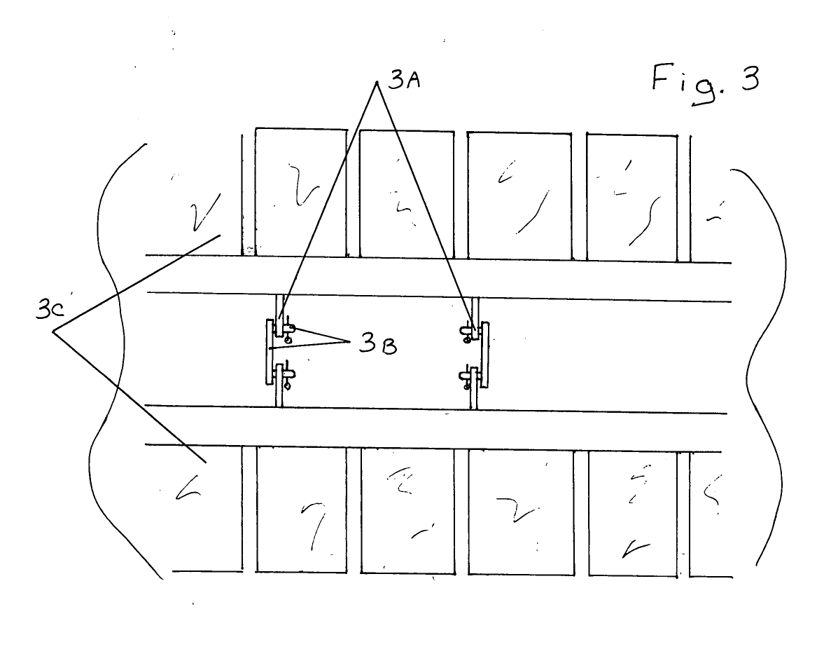

FIG. 3 illustrates a view of mechanically linked modules 3A. A plurality of double-sided clevis pins 3B are employed to form rows of co-planar modules 4 adjacent to each other.

Modules 3C are mechanically coupled to adjacent modules 3C via clevis pin couplers 3B positioned between module the modules as shown in FIG. 3, which allow for stacking of modules one on top of another, when not deployed, and when deployed, to accommodate variation in landscape features.

Electrical interconnections 1A between solar cell modules are also well known. See for example Makita et al., U.S. Pat. No. 6,331,671 issued Dec. 18, 2001.

The modes of transport of electrical currents from the modules to batteries, for example, are well known within the modular solar cell art. The positive and negative output leads from each module would be connected to the positive and negative buses, in turn connected to vehicle battery charger station 4A and emergency staff buildings 4B. The rows of modules maybe electrically coupled together by electrical cord and plugs or other conventional devices.

While the invention has been described in connection with preferred embodiments, the description is not intended to limit the scope of the invention to the particular forms set forth, but on the contrary, it is intended to cover such alternatives, modifications, and equivalents as may be included within the spirit and scope of the invention as indicated by the language of the appended claims. For example, the transparent sheet overlaying the cells may possibly be separate from the module itself. Also, invention is intended to include a possible application whereby the modules could be positioned as temporary electrical generators in high traffic areas like breakdown lanes on highways or between railroad rails. Also, the rectangular array need not be designed for containing rectangular cells but could have other shapes such as hexagonal or square shapes.

What is claimed is:

1. A system for enabling the rapid, non-permanent deployment on substantially horizontal areas for generating electrical power by employing solar energy comprising:
(a) an array of a substantial number of solar cell modules, positioned upon surfaces of said horizontal areas, and
(b) wherein said solar cell modules are configured to support the weight of pedestrians or vehicles present upon said horizontal areas without damaging said solar cell modules.

2. The system of claim 1 wherein said horizontal areas consist of parking lots for automobiles.

3. The system of claim 2 wherein said horizontal areas are positioned at peripheral portions of said parking lots where parked vehicles are less numerous, whereby greater amounts of solar energy are recovered.

4. The system of claim 1 wherein said horizontal areas are airport parking areas, runways or taxi ways.

5. The system of claim 1 wherein said horizontal areas are sparsely traveled roads or driveways.

6. The system of claim 1 wherein said horizontal areas are areas set aside for pedestrians or bicyclists.

7. A system for enabling dual use of substantially horizontal areas used for supporting the weight of vehicles or pedestrians and for generating electric power by employing solar energy comprising:
(a) an array of a substantial number of solar cell modules positioned upon said horizontal areas; and
(b) wherein said solar cell modules include frame members that have sufficient strength for absorbing compressive forces of said vehicles or pedestrians without damaging said solar cell modules.

8. The system of claim 7 wherein frame members of a first group of modules are mechanically coupled to adjacent frame members of a second group of modules via double sided clevis pins positioned between said first and second groups of modules.

9. The system of claim 7 wherein said modules also have load bearing honeycomb configurations containing solar cells.

11. The system of claim 7 wherein said horizontal areas consist of emergency or temporary base camp structural surface.

12. The system of claim 7 wherein said horizontal areas are airport parking areas, runways or taxi ways.

13. The system of claim 7 wherein said horizontal areas are sparsely traveled roads or driveways.

14. The system of claim 7 wherein said horizontal areas are areas set aside for pedestrians or bicycle transport.

15. The system of claim 7 wherein said horizontal areas are high traffic areas, breakdown lanes, bridges, or active roadways.

16. The system of claim 7 wherein said horizontal areas are on railroad ties between rails.

17. The system of claim 9 wherein said solar cells are shaped as rectangles.

18. A system for enabling dual use of substantially horizontal areas used for supporting the weight of vehicles or pedestrians and for generating electric power by employing solar energy comprising:
(a) an array of a substantial number of solar cell modules positioned upon said horizontal areas; and
(b) wherein said solar cell modules have wall members that have sufficient strength for absorbing compressive forces of said vehicles or pedestrians without damaging said solar cell modules; and wherein
(c) said wall members include frame members positioned near edge portions of said solar cell modules and honeycomb partitions containing solar cells.

19. The system of claim 18 wherein frame members of a first group of modules are mechanically coupled to adjacent frame members of a second group of modules via double sided clevis pins positioned between said first and second groups of modules.

20. The system of claim 18 wherein frame members of a first group of modules are electrically coupled to adjacent frame members of a second group of modules via electric cables and plugs positioned between said first and second modules.

21. The system of claim 18 wherein said horizontal areas are positioned at peripheral portions of parking lots where parked vehicles are less numerous, whereby greater amounts of solar energy are recovered.

22. The system of claim 18 wherein said horizontal areas are areas set aside for pedestrians or bicycle transport.
